(19) United States
(12) Patent Application Publication
(10) Pub. No.: US 2012/0164439 A1
(43) Pub. Date: Jun. 28, 2012

(54) HEAT DISSIPATING SUBSTRATE AND METHOD FOR MANUFACTURING THE SAME

(75) Inventor: YUNG SHENG HUANG, NEW TAIPEI CITY (TW)

(73) Assignee: ULTRAPACK ENERGY CO., LTD., YANGMEI CITY (TW)

(21) Appl. No.: 13/337,531

(22) Filed: Dec. 27, 2011

(30) Foreign Application Priority Data
Dec. 28, 2010 (TW) 099146267

(51) Int. Cl. B32B 18/00; C23C 14/34; B05D 5/12; C23C 14/35; B32B 5/00

(52) U.S. Cl. 428/336; 428/448; 428/698; 428/701; 428/688; 427/126.2; 204/192.22

(57) ABSTRACT

The present invention relates to a heat dissipating substrate and a method for manufacturing the same. The heat dissipating substrate comprises a substrate and a ceramic layer with thermal conduction and electrical insulation disposed on the substrate. In addition, the ceramic thermally conductive and electrically insulating layer has a plurality of sheet structures stacked on each other. Because the plurality of sheet structures have a buffer space, the ceramic thermally conductive and electrically insulating layer is buffered during thermal expansion.

### FIELD OF THE INVENTION

The present invention relates generally to a heat dissipating substrate and a method for manufacturing the same, and particularly to a manufacturing method and a structure for adhering a ceramic layer with thermal conduction and electrical insulation to a metal substrate.

### BACKGROUND OF THE INVENTION

As global warming is getting severer, people take the subject of environmental protection seriously. The representatives of all countries worldwide met for the topic of world climate in Copenhagen at the end of 2009 to discuss the future of the earth. They endeavored using utmost wisdom to reach a common consensus on environmental protection of the earth. In the electronic industry, light emitting diode's (LED) advantage of power saving is always a hot topic. In 2010, due to the applications of LED TV and lighting, LED has exhibited high growth rate. The overall output value has grown approximately by 15% to the previous year. Due to its advantages of low power consumption and long life, instead of being a normal electronic component, LED has become an important power saving product. Thereby, the applications of LED products are attracting people's attention.

Because of their superior advantages including low power consumption, sufficient brightness, and small size, LEDs have become a device widely adopted in lighting apparatuses such as flashlights and light bulbs. They even have replaced traditional tungsten lamps, and become the mainstream product in small light apparatuses and the most preferred choice of consumers. Although such LEDs own the advantages of low power consumption and high brightness, the temperature during their operation is relatively high. If the heat generated during operation cannot be dissipated appropriately, it might be harmful to the LEDs and the peripheral circuitry or even affecting their lifetime.

Current packaging methods for LED products mainly include wire-bonding and flip-chip methods. The products are both single crystalline and polycrystalline. The most critical technology is how to dissipate the heat accumulated during the light emitting process after LEDs are packaged. Heat dissipation is determined by conduction and convection. Area is the most important parameter for achieving the purposes of maintaining stable light emitting efficiency. In the past, the packing method of LED chips is to put them on a metal substrate and then cover them with resins. Nonetheless, by covering with resins, which have low thermal conductivity, the generated heat will be conducted through the metal substrate. The thermal expansion coefficient of the metal is much greater than that of LED chips. Thereby, excess expansion will lead to thermal strain on the substrate, and thus inducing defects in the chips or lowering in light emitting efficiency. Based on the problems described above, according to various types and characteristics of heat dissipating substrates for LED, the package of LEDs has adopted low-cost printed circuit boards or metal-core printed circuit boards for heat dissipation. Although this method can enhance the heat dissipating effectively, using high polymer as the major substrate cannot sustain high-temperature operations. Hence, there are many limitations on high-power LED packages. At present, diamond is the material having highest hardness, fastest heat dissipation, and most anti-erosive. Accordingly, diamond, which has superior thermal conductivity and mechanical strength, is selected as the target of the material for future substrate. However, the price of the material is costly and it is difficult for mass production.

In considering the problems described above, most heat dissipating substrates in LED packages adopt ceramic materials, which have good competitiveness. In addition, by taking advantage of similar thermal expansion coefficient to semiconductors and high heat tolerance, ceramic substrates can solve the problems of thermal strain and high-temperature processes effectively. Recently, there are many applications of high-power ceramic heat-dissipating substrates for LEDs. Nevertheless, because the thick-film process is adopted for preparing metal circuitry in LTCC/HTCC, the accuracy of circuits is not good. Besides, the cost of materials is expensive. Considering the limitations imposed by the fabrication process, it is not a cost effective method, making it not suitable for small-sized high-power products. On the other hand, DBC is also limited by the process capability with the circuit resolution of 100-300 um. Moreover, its capability in mass production is limited by the problem of air voids at the interface between metal and ceramic materials. The considering points for ceramic substrate products lie on circuit accuracy, heat dissipating coefficient, uniformity on metal surface, and adherence between metal and ceramics.

Accordingly, the present invention provides a heat dissipating substrate and a method for manufacturing the same. According to the present invention, the microstructures of a ceramic thermally conductive and electrically insulating layer are stacked on a substrate in sheets. The heat dissipating substrate according to the present invention has more voids between its microstructures for preventing separation phenomena during thermal expansion and hence improving the lifetime of the metal heat dissipating substrate. Besides, the thermal conductive ceramic thin film of the heat dissipating substrate according to the present invention has high thermal conductivity, which is beneficial to the heat dissipating performance of high heat emitting devices. The manufacturing method according to the present invention is simple, and thus reducing the manufacturing cost drastically.

### SUMMARY

An objective of the present invention is to provide a heat dissipating substrate and a method for manufacturing the same. A ceramic layer with thermal conduction and electrical insulation is formed on a substrate. The ceramic layer has a plurality of sheet structures. The sheet microstructures are manufactured by adopting the manufacturing method of stacking aluminum nitride thin films.

For achieving the objective described above, the heat dissipating substrate and the method for manufacturing the same stack sheet microstructures on a substrate for forming a ceramic layer with thermal conduction and electrical insulation by using vacuum sputtering, thermal evaporation deposition, or vapor deposition. There more voids between microstructures, and thus preventing separation phenomena during thermal expansion.

### BRIEF DESCRIPTION OF THE DRAWINGS

FIG. 1 shows a schematic diagram according to a preferred embodiment of the present invention;

FIG. 2 shows a cross-sectional view according to a preferred embodiment of the present invention;

FIG. 3 shows a flowchart according to a preferred embodiment of the present invention;

FIG. 4 shows a schematic diagram of the apparatus according to a preferred embodiment of the present invention; and

FIG. 5 shows an SEM picture according to preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The present invention relates to a heat dissipating substrate. According to the present invention, the problem of thin-film separation phenomena cause by different thermal expansion coefficients of the substrate and the aluminum nitride thin film while forming the aluminum nitride thin film on the metal substrate in the process according to the prior art. The present invention provides a heat dissipating substrate and a method for manufacturing the same, which stack sheet microstructures on a substrate for forming a ceramic layer with thermal conduction and electrical insulation by using vacuum sputtering, thermal evaporation deposition, or vapor deposition. Because of the buffer space between the sheet structures, no separation phenomena will occur during thermal expansion.

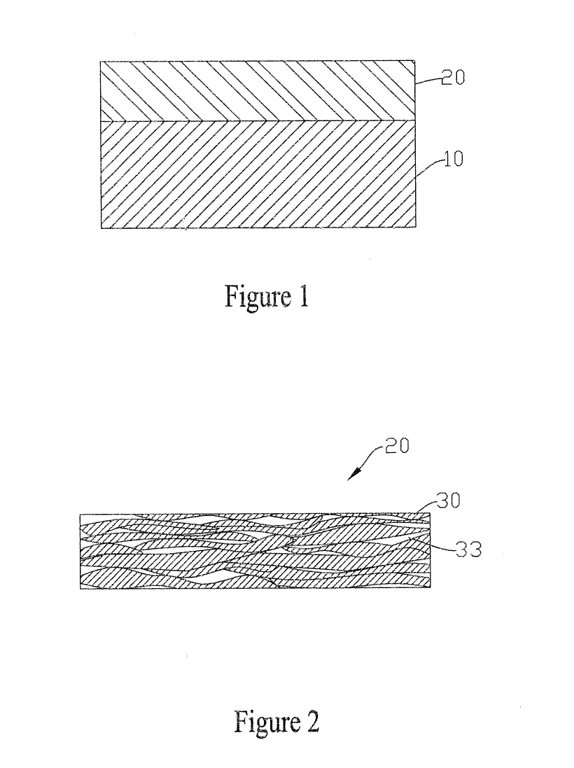

FIG. 1 and FIG. 2 show a schematic diagram and a cross-sectional view according to a preferred embodiment of the present invention. As shown in the figures, the present embodiment provides the heat dissipating substrate, which comprises a substrate 10 and a ceramic layer 20 with thermal conduction and electrical insulation.

The ceramic layer 20 with thermal conduction and electrical insulation is disposed on the substrate 10 and has a plurality of sheet structures 30. The plurality of sheet structures 30 stack on each other and have a buffer space 33 therebetween. The thickness of the ceramic layer 20 is 1˜10 um. Besides, the substrate is aluminum or copper. The ceramic layer 20 is aluminum nitride, aluminum oxide, silicon carbide, or boron nitride.

Due to its high thermal: conductivity, the ceramic thin film with thermal conductivity of the heat dissipating substrate according to the present invention can improve the heat dissipating performance of high heat-emitting devices. The thermal expansion coefficients of aluminum nitride, copper, and aluminum are 5 ppm/K, 17 ppm/K, and 25 ppm/K, respectively. Because the aluminum nitride has the smallest thermal expansion coefficient, the present selects it as the material for the ceramic layer 20 with thermal conduction and electrical insulation of the heat dissipating substrate. However, the present invention is not limited to the material. According to the prior art, the sintering method is adopted for forming an aluminum nitride layer on a metal substrate, and hence making the aluminum nitride layer composed or tightly crystallized microstructures. During thermal expansion, the aluminum nitride and the substrate will extrude each other due to unduly narrow buffer spaces and consequently fractures may occur. According to the present invention, the ceramic layer 20 with thermal conduction and electrical insulation is formed by stacking sheet microstructures on the substrate. Due to the buffer space 33 between the plurality sheet structures, separation phenomena can be prevented during thermal expansion and thus improving the lifetime of the metal heat dissipating substrate. In addition, if only the buffer space 33 is sufficiently large, the material of the ceramic layer 20 is not limited to aluminum nitride.

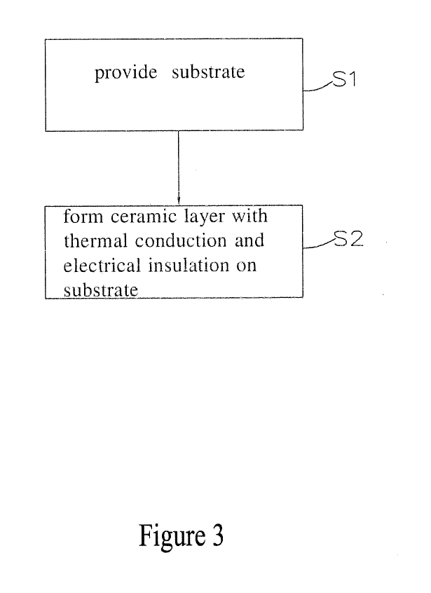

FIG. 3 shows a flowchart according to a preferred embodiment of the present invention. As shown in the figure, the method for manufacturing the heat dissipating substrate according to the present embodiment is described. First, as shown in the step S1, provide a substrate 10. Then, as shown in the step S2, form a ceramic layer 20 with thermal conduction and electrical insulation on the substrate 10. The ceramic layer 20 has a plurality of sheet structures 30 stacking on each other.

The ceramic layer 20 with thermal conduction and electrical insulation is aluminum nitride, aluminum oxide, silicon carbide, or boron nitride; the substrate is aluminum or copper. Besides, the thickness of the ceramic layer 20 with thermal conduction and electrical insulation is 1˜10 um. The ceramic layer 20 with thermal conduction and electrical insulation is formed on the substrate 10 by vacuum sputtering, thermal evaporation deposition, or chemical vapor deposition.

In order to make the characteristics as well as the technical content of the present invention to be further understood, the detailed description and drawings of the present invention are provided as follows. However, the drawings are provided for reference and description, not used for limiting the present invention.

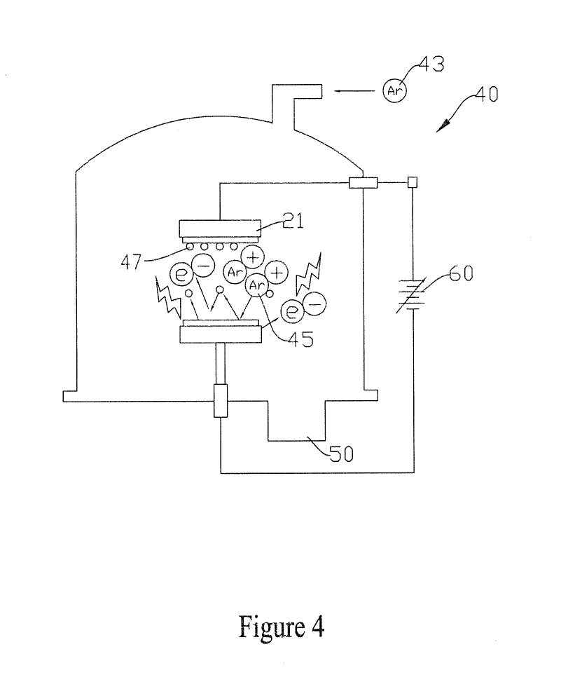

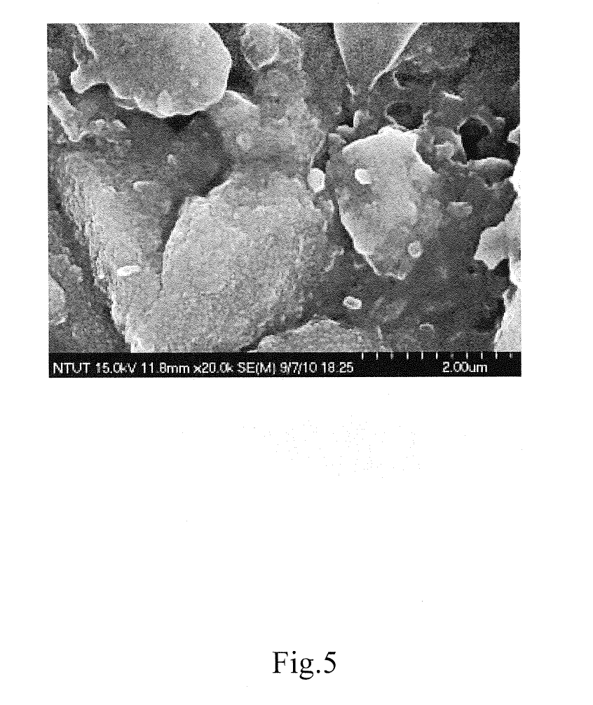

FIG. 4 shows a schematic diagram of the apparatus according to a preferred embodiment of the present invention. According to the present embodiment, magnetically controlled sputtering for sputtering a target material is used as an example. Please refer to FIG. 5 together. FIG. 5 shows an SEM picture according to preferred embodiment of the present invention. First, put the substrate 10 and the ceramic layer 20 with thermal conduction and electrical insulation into the vacuum chamber 40. The substrate 10 is disposed at the positive electrode and the ceramic layer 20 with thermal conduction and electrical insulation is disposed on a plane 21 and acts as the negative electrode. A pumping system 50 exhausts the vacuum chamber 40 to the vacuum state with the air pressure between 10⁻⁵ and 10⁻² torr. Then, a DC or high-frequency power supply 60 is applied. The voltage of the power supply 60 is between 300 and 700 volts; the power of the power supply 60 is between 0.5 and 3 KW. Next, aerate argon 43 or argon/nitrogen mixture gas into the vacuum chamber 40. The ratio of the argon/nitrogen mixture gas is between 9:1 and 3:7. The ceramic layer 20 with thermal conduction and electrical insulation is grounded by the negative electrode. A plurality of argon atoms are ionized to generate a plurality of argon ions 45. The plurality of argon ions 45 are attracted by the ceramic layer 20 and bombard the ceramic layer 20. The plurality of argon ions 45 sputter the atoms 47 in the ceramic thermally conductive and electrically insulating layer 20. The sputtered atoms 47 form thin-film deposition via sputtering. The time required according to the present embodiment is between 40 and 120 minutes.

The method for manufacturing the heat dissipating substrate according to the present invention is different from the prior art. According to the prior art, the sintering method is adopted for forming an aluminum nitride thin film on a metal substrate, and hence making the aluminum nitride thin film composed of tightly crystallized microstructures. Nonetheless, the tightly crystallized microstructures of the thin film will suffer the separation phenomena because the thermal expansion coefficients of the substrate and the aluminum nitride are different. According to the present invention, the microstructures are formed by sheet stacks and hence having more voids, which can prevent the separation phenomena between the substrate and the aluminum nitride thin film during thermal expansion. Thereby, the lifetime of the metal heat dissipating substrate can be improved.

To sum up, according to the heat dissipating substrate and the method for manufacturing the same of the present invention, an aluminum nitride thin film having stacked sheets of microstructures can be formed. Because there arc more voids between the microstructures, no separation phenomena will occur during thermal expansion. The present invention relates to a heat dissipating substrate and a method for manufacturing the same. The method according to the present invention includes providing a substrate and forming a ceramic layer with thermal conduction and electrical insulation on the substrate. The ceramic layer has a plurality of sheet structures stacked on each other. Besides, there is a buffer space between the plurality of sheet structures so that no separation phenomena caused by difference in thermal expansion coefficients may occur.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A heat dissipating substrate, comprising:
a substrate; and
a ceramic layer with thermal conduction and electrical insulation, disposed on said substrate, having a plurality of sheet structures stacked on each other.

2. The heat dissipating substrate of claim 1, wherein said substrate is aluminum or copper.

3. The heat dissipating substrate of claim 1, wherein said ceramic layer is aluminum nitride, aluminum oxide, silicon carbide, or boron nitride.

4. The heat dissipating substrate of claim 1, wherein the thickness of said ceramic layer is 1˜10 um.

5. The heat dissipating substrate of claim 1, wherein said plurality of sheet structures have a buffer space therebetween.

6. A method for manufacturing a heat dissipating substrate, comprising steps of:
providing a substrate; and
forming a ceramic layer with thermal conduction and electrical insulation on said substrate, and said ceramic layer has a plurality of sheet structures stacked on each other.

7. The method for manufacturing a heat dissipating substrate of claim 6, wherein said ceramic layer is aluminum nitride, aluminum oxide, silicon carbide, or boron nitride.

8. The method for manufacturing a heat dissipating substrate of claim 6, wherein the thickness of said ceramic layer is 1˜10 um.

9. The method for manufacturing a heat dissipating substrate of claim 6, wherein said ceramic layer is formed on said substrate by the sputtering method.

10. The method for manufacturing a heat dissipating substrate of claim 9, wherein said sputtering method includes vacuum sputtering and magnetically controlled sputtering.

11. The method for manufacturing a heat dissipating substrate of claim 10, wherein the gas for operating said magnetically controlled sputtering is argon or argon/nitrogen mixture gas.

12. The method for manufacturing a heat dissipating substrate of claim 10, wherein the air pressure for operating said magnetically controlled sputtering is 10⁻⁵˜10⁻² torr.

13. The method for manufacturing a heat dissipating substrate of claim 11, wherein the ratio of said argon/nitrogen mixture gas is 9:1˜3:7.

14. The method for manufacturing a heat dissipating substrate of claim 6, wherein said ceramic layer is formed on said substrate by the thermal evaporation deposition method.

15. The method for manufacturing a heat dissipating substrate of claim 6, wherein said ceramic layer is formed on said substrate by the chemical vapor deposition method.
